(19) United States
(12) Patent Application Publication
(10) Pub. No.: US 2026/0266931 A1
(43) Pub. Date: Sep. 10, 2026

(54) MAGNETIC SENSOR

(71) Applicant: Alps Alpine Co., Ltd., Tokyo (JP)

(72) Inventors: Kanta KIKUCHI, Niigata-ken (JP); Eiji UMETSU, Niigata-ken (JP)

(21) Appl. No.: 19/660,919

(22) Filed: Apr. 28, 2026

Related U.S. Application Data
(63) Continuation of application No. PCT/JP2024/040994, filed on Nov. 19, 2024.

(30) Foreign Application Priority Data
Dec. 14, 2023 (JP) 2023-211309

(51) Int. Cl. G01R 33/09; G01R 33/00; H10N 50/10

(52) U.S. Cl. CPC G01R 33/093; G01R 33/0011; G01R 33/098; H10N 50/10

(57) ABSTRACT

A magnetic sensor includes a first magnetic body and a second magnetic body spaced apart from each other in a first direction, a magnetoresistance effect element having a sensitivity axis parallel to the first direction and located between the first magnetic body and the second magnetic body in the first direction, first wiring lines located on a second direction side, the second direction being orthogonal to the first direction, of the first magnetic body, the first wiring lines being configured, when energized, to generate a magnetic field such that magnetic flux passing through the first magnetic body has a component in the first direction, and an insulating section located between the first wiring lines and the first magnetic body.

### CLAIM OF PRIORITY

This application is a Continuation of International Application No. PCT/JP2024/040994 filed on Nov. 19, 2024, which claims benefit of Japanese Patent Application No. 2023-211309 filed on Dec. 14, 2023. The entire contents of each application noted above are hereby incorporated by reference.

### BACKGROUND OF THE INVENTION

### 1. Field of the Invention

The present invention relates to a magnetic sensor.

### 2. Description of the Related Art

Japanese Unexamined Patent Application Publication No. 2018-115972 discloses a magnetic sensor that includes a substrate, a magnetic sensing unit that includes a stacked section disposed on the substrate, the stacked section including a free magnetic layer whose magnetization changes in accordance with an external magnetic field, a pinned magnetic layer whose magnetization is fixed in a first direction, and a non-magnetic layer disposed between the free magnetic layer and the pinned magnetic layer, the magnetic sensing unit being configured to output a signal corresponding to the external magnetic field, and a magnetic field generating section configured to apply a bias magnetic field to the free magnetic layer. When the bias magnetic field is not applied to the free magnetic layer, a magnetization direction of the free magnetic layer is substantially parallel or substantially antiparallel to the first direction, and the magnetic sensor is configured to calculate a component of the external magnetic field in a second direction that is perpendicular to the first direction in plan view based on a first output that is an output of the magnetic sensing unit in a state in which a first bias magnetic field including a positive component in the second direction is applied to the free magnetic layer, and a second output that is an output of the magnetic sensing unit in a state in which a second bias magnetic field including a negative component in the second direction is applied to the free magnetic layer.

In the invention disclosed in Japanese Unexamined Patent Application Publication No. 2018-115972, a specific example of the magnetic field generating section is a wiring line that is provided in the stacking direction of the stacked section, and a magnetic field generated by the energized wiring line is applied to the free magnetic layer of the stacked section as a bias magnetic field. An external magnetic field is measured in a state in which bias magnetic fields that have different application directions are applied, and 1/f noise is removed based on the measurement results.

As in the magnetic sensor disclosed in Japanese Unexamined Patent Application Publication No. 2018-115972, when an external magnetic field is measured under magnetic fields generated by a wiring line disposed in the vicinity of a magnetoresistance effect element, it may be difficult to increase the strength of the generated magnetic field by increasing the current flowing through the wiring line due to the small cross-sectional area of the wiring line, structural difficulty in dissipating Joule heat generated by the wiring line, or other factors.

In view of the above, the present invention is directed to providing a magnetic sensor capable of efficiently applying a magnetic field generated by wiring lines disposed in the vicinity of a magnetoresistance effect element.

### SUMMARY OF THE INVENTION

A magnetic sensor according to an aspect of the present invention that solves the above-described problem includes a first magnetic body and a second magnetic body spaced apart from each other in a first direction, a magnetoresistance effect element having a sensitivity axis parallel to the first direction and located between the first magnetic body and the second magnetic body in the first direction, first wiring lines located on a second direction side, the second direction being orthogonal to the first direction, of the first magnetic body, the first wiring lines being configured, when energized, to generate a magnetic field such that magnetic flux passing through the first magnetic body has a component in the first direction, and an insulating section located between the first wiring lines and the first magnetic body.

Since a bias magnetic field generated by energization of wiring lines can be efficiently applied to a magnetoresistance effect element, the current density in the wiring lines can be reduced, and thus Joule heat generated by the wiring lines can be suppressed.

The magnetic sensor may include second wiring lines disposed on the second-direction side of the second magnetic body with the insulating section therebetween, the second wiring lines being configured, when energized, to generate a magnetic field such that magnetic flux passing through the second magnetic body has a component in the first direction. In this case, a direction of the component in the first direction of the magnetic flux passing through the first magnetic body in accordance with the magnetic field generated by energization of the first wiring lines may be the same as a direction of the component in the first direction of the magnetic flux passing through the second magnetic body in accordance with the magnetic field generated in the second magnetic body by energization of the second wiring lines. In the magnetic sensor, the insulating section may include a diffusion suppression section. By configuring the insulating section to function as a diffusion suppression section, material transfer (diffusion) between the wiring lines and the magnetic body can be suppressed, thereby reducing degradation in function due to the diffusion. The above-described diffusion is expected to occur during the manufacturing process (particularly when heated) and during use (due to temporal changes). In the magnetic sensor, the first wiring lines may be provided on both sides of the first magnetic body in the second direction. In the magnetic sensor, the second wiring lines may be provided on both sides of the second magnetic body in the second direction. The magnetic sensor may include a first magnetic flux concentration section that is provided on a side of the first wiring lines opposite to a side facing the first magnetic body and includes a ferromagnetic material. The magnetic sensor may include a second magnetic flux concentration section that is provided on a side of the second wiring lines opposite to a side facing the second magnetic body and includes a ferromagnetic material. The magnetic sensor may include a first magnetic flux concentration section that is provided on a side of the first wiring lines opposite to a side facing the first magnetic body and includes a ferromagnetic material. In the magnetic sensor, as viewed in the second direction, the magnetoresistance effect element may not overlap either the first magnetic flux concentration section or the second magnetic flux concentration section. In the magnetic sensor, the first magnetic flux concentration section and the second magnetic flux concentration section may be continuously connected in the first direction.

### BRIEF DESCRIPTION OF THE DRAWINGS

FIG. 1 is a circuit diagram illustrating a magnetic sensor according to an embodiment of the present invention;

FIG. 2 is a cross-sectional view taken along line II-II in FIG. 1;

FIG. 3 is a diagram illustrating a magnetic field generated by energization of wiring lines;

FIG. 4 is a cross-sectional view illustrating a structure of a magnetic sensor according to another embodiment of the present invention;

FIG. 5 is a cross-sectional view illustrating a structure of a magnetic sensor according to a first modification of another embodiment of the present invention;

FIG. 6 is a cross-sectional view illustrating a structure of a magnetic sensor according to a second modification of another embodiment of the present invention;

FIG. 7 is a cross-sectional view illustrating a structure of a magnetic sensor according to a third modification of another embodiment of the present invention;

FIG. 8 is a cross-sectional view illustrating a structure of a magnetic sensor according to a fourth modification of another embodiment of the invention;

FIG. 9 is a cross-sectional view illustrating a structure of a magnetic sensor according to a related art;

FIG. 10 is a diagram showing a simulation result of a magnetic field generated by a first magnetic field generating section MG1x;

FIG. 11 is a diagram showing a simulation result of a magnetic field generated by a first magnetic field generating section MG1b;

FIG. 12 is a diagram showing a simulation result of a magnetic field generated by a first magnetic field generating section MG1a; and

FIG. 13 is a diagram showing a simulation result of a magnetic field generated by a first magnetic field generating section MG1c.

### DESCRIPTION OF THE PREFERRED EMBODIMENTS

Hereinafter, embodiments of the present invention will be described with reference to the drawings. In the following descriptions, the same reference numerals are given to the same components and descriptions of the components described once will be omitted as appropriate.

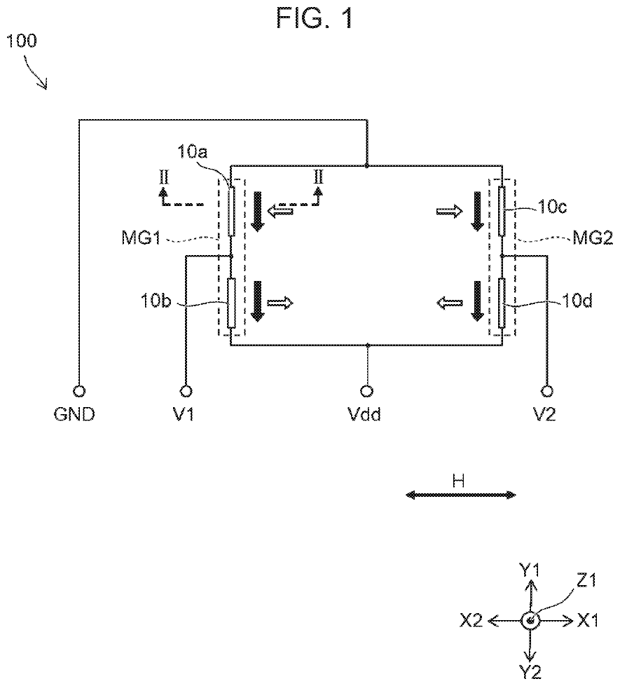

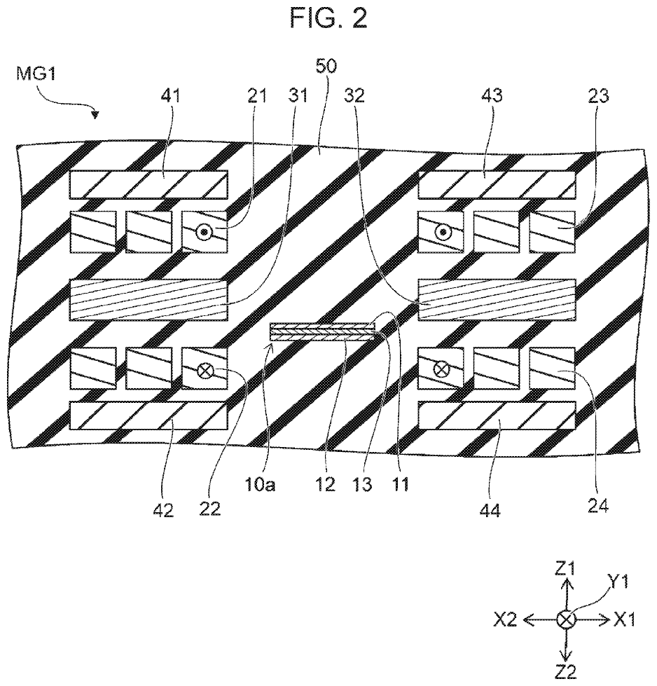

FIG. 1 is a circuit diagram illustrating a magnetic sensor according to an embodiment of the present invention. FIG. 2 is a cross-sectional view taken along line II-II in FIG. 1. As illustrated in FIG. 1, a magnetic sensor 100 according to an embodiment of the present invention includes magnetoresistance effect elements 10a, 10b, 10c, and 10d (when these elements are not distinguished, they are referred to as magnetoresistance effect elements 10 as appropriate). The four magnetoresistance effect elements 10 may be provided on the same substrate (one chip). In this embodiment, the four magnetoresistance effect elements 10 are provided on the same substrate (not illustrated). FIG. 1 is a diagram illustrating the magnetic sensor 100 viewed from a stacked surface (front surface) of the substrate in the direction of the normal to the substrate. More specifically, in FIG. 1, the Z1 side in the Z1-Z2 direction denotes the front side of the substrate, and the Z2 side in the Z1-Z2 direction denotes the rear side of the substrate. It should be noted that the Z1-Z2 direction is parallel to the stacking direction of the magnetoresistance effect element 10.

The magnetic sensor 100 includes, between a power supply terminal Vdd, which is a power supply feeding point, and a ground terminal GND, a first half-bridge circuit that includes a magnetoresistance effect element 10a and a magnetoresistance effect element 10b both extending in the Y1-Y2 direction and connected in series, and a second half-bridge circuit that includes a magnetoresistance effect element 10c and a magnetoresistance effect element 10d both extending in the Y1-Y2 direction and connected in series, which are connected in parallel.

The first half-bridge circuit includes an output terminal V1 between the magnetoresistance effect element 10a and the magnetoresistance effect element 10b. The second half-bridge circuit includes an output terminal V2 between the magnetoresistance effect element 10c and the magnetoresistance effect element 10d. Based on a potential difference (Va-Vb, midpoint potential difference) of outputs of the two output terminals V1 and V2, the magnitude of an external magnetic field that is externally applied as a detection magnetic field H can be quantitatively measured.

The pair of magnetoresistance effect elements 10a and 10b of the first half-bridge circuit include pinned magnetic layers 11 that have magnetization directions in the X2 direction in the X1-X2 direction and in the X1 direction in the X1-X2 direction, respectively, as indicated by the white arrows in FIG. 1. The pair of magnetoresistance effect elements 10c and 10d of the second half-bridge circuit include pinned magnetic layers 11 that have magnetization directions in the X1 direction in the X1-X2 direction and in the X2 direction in the X1-X2 direction, respectively, as indicated by the white arrows in FIG. 1.

In the first half-bridge circuit and the second half-bridge circuit, the magnetization directions of the pinned magnetic layers 11 in the magnetoresistance effect elements 10a and 10c on the ground terminal GND side are opposite (anti-parallel). The magnetization directions of the pinned magnetic layers 11 in the magnetoresistance effect elements 10b and 10d on the power supply terminal Vdd side are opposite (anti-parallel). Accordingly, sensitivity axis directions of the magnetoresistance effect elements 10 extend in the X1-X2 direction, and in this specification, the sensitivity axis directions are also referred to as a “first direction”.

The magnetization directions (directions of bias magnetic fields) of free magnetic layers 12 in the four magnetoresistance effect elements 10a to 10d are the same in a state in which no external magnetic field is applied, and the magnetization directions are parallel to the Y2 direction in the Y1-Y2 direction, as indicated by the black arrows in FIG. 1.

With the above-described configuration, as the magnitude of a detection magnetic field H in the X1-X2 direction changes, the output of the output terminal V1 from the first half-bridge circuit and the output of the output terminal V2 from the second half-bridge circuit change in opposite directions. As a result, a large output can be obtained as a potential difference between the two output terminals V1 and V2. Accordingly, the magnetic sensor 100 can detect the detection magnetic field H with high accuracy. It should be noted that, instead of the full-bridge circuits, the first or second half-bridge circuit or the magnetoresistance effect elements 10 may be used.

As illustrated in FIG. 2, the magnetoresistance effect element 10a may be, for example, a giant magnetoresistance effect (GMR) element or a tunneling magnetoresistance effect (TMR) element. The magnetoresistance effect element 10a includes the pinned magnetic layer 11, the free magnetic layer 12, and an intermediate layer 13 that is formed between the pinned magnetic layer 11 and the free magnetic layer 12. A resistance value of the magnetoresistance effect element 10a changes depending on the relative relationship between the magnetization direction of the pinned magnetic layer 11, whose magnetization direction is fixed, and the free magnetic layer 12, whose magnetization direction changes depending on an external magnetic field. The magnetic sensor 100 can measure the direction and strength of an external magnetic field to be measured based on a change in the resistance value of the magnetoresistance effect element 10a.

When the magnetoresistance effect element 10a is a GMR element, the pinned magnetic layer 11 includes a ferromagnetic layer formed of a material such as a cobalt-iron alloy (CoFe alloy). The free magnetic layer 12 includes a soft magnetic material such as a CoFe alloy, a nickel-iron alloy (NiFe alloy), or the like and has a single-layer structure, a multilayer structure, a multilayer ferrimagnetic structure, or the like. The intermediate layer 13 includes a non-magnetic intermediate layer formed of a non-magnetic material such as Cu.

To stabilize the output of the magnetic sensor 100, a bias magnetic field is applied to the free magnetic layer 12 in a direction orthogonal to the sensitivity axis direction (the first direction) parallel to the X1-X2 direction. In the magnetic sensor 100 according to the embodiment, the direction of the bias magnetic field is the Y2 direction in the Y1-Y2 direction as illustrated in FIG. 1. This configuration enables the soft magnetic material in the free magnetic layer 12 to have an aligned magnetization direction when no magnetic field is applied.

As described above, the magnetization direction of the pinned magnetic layer 11 of the magnetoresistance effect element 10a is fixed in the X2 direction in the X1-X2 direction, and when no magnetic field is applied, the magnetization direction of the free magnetic layer 12 extends in the Y2 direction in the Y1-Y2 direction, which is orthogonal to the magnetization direction of the pinned magnetic layer 11. Accordingly, resistance values of the magnetoresistance effect element 10a change in opposite directions depending on whether the direction of a detection magnetic field H is the X1 direction or the X2 direction in the X1-X2 direction. More specifically, the resistance values exhibit odd function characteristics with respect to the detection magnetic field H in the X1-X2 direction, and thus the directions and magnitudes of the detection magnetic field H can be continuously measured.

A TMR element may be used as the magnetoresistance effect element 10a instead of the above-described GMR element. In such a case, the intermediate layer 13 serves as an insulating barrier layer that includes a material such as MgO, Al₂O₃, titanium oxide, or the like.

The magnetoresistance effect elements 10b to 10d have a basic structure in common with the magnetoresistance effect element 10a. To increase the measurement accuracy, the magnetoresistance effect elements 10a to 10d are preferably manufactured on the same substrate through a common manufacturing process.

As illustrated in FIG. 1, a first magnetic field generating section MG1 is provided in the vicinity of the magnetoresistance effect elements 10a and 10b, and a second magnetic field generating section MG2 is provided in the vicinity of the magnetoresistance effect elements 10c and 10d. In the magnetic sensor 100, the first magnetic field generating section MG1 and the second magnetic field generating section MG2 have the same structure.

As illustrated in FIG. 2, the first magnetic field generating section MG1 includes first wiring lines 21 and 22, a first magnetic body 31, and first magnetic flux concentration sections 41 and 42, which are disposed on the X2 side in the X1-X2 direction (first direction) of the magnetoresistance effect element 10a; second wiring lines 23 and 24, a second magnetic body 32, and second magnetic flux concentration sections 43 and 44, which are disposed on the X1 side in the X1-X2 direction (first direction); and an insulating section 50 disposed at least between the first wiring lines 21 and the first magnetic body 31, and between the first wiring lines 22 and the first magnetic body 31, and between the second wiring lines 23 and the second magnetic body 32, and between the second wiring lines 24 and the second magnetic body 32.

The first magnetic body 31 and the second magnetic body 32 that extend in the Y1-Y2 direction each include a soft magnetic material such as permalloy, and are disposed apart from each other in the first direction. The magnetoresistance effect element 10a is located between the first magnetic body 31 and the second magnetic body 32 in the first direction. In the first magnetic field generating section MG1 illustrated in FIG. 2, from the viewpoint of manufacturability and the like, the magnetoresistance effect element 10a is disposed between the first magnetic body 31 and the second magnetic body 32 at a position shifted toward one side in the Z1-Z2 direction, which is parallel to the stacking direction of the magnetoresistance effect element 10a, specifically toward the Z2 side.

On the Z1 side in the Z1-Z2 direction of the first magnetic body 31, the first wiring lines 21 that extend in the Y1-Y2 direction are disposed, and on the Z2 side in the Z1-Z2 direction of the first magnetic body 31, the first wiring lines 22 that extend in the Y1-Y2 direction are disposed. In this specification, the directions in which the first wiring lines 21 and 22 are disposed with respect to the first magnetic body 31 and the second wiring lines 23 and 24 are disposed with respect to the second magnetic body 32 are referred to as a “second direction”. In the magnetic sensor 100 according to the embodiment illustrated in FIG. 2 and other drawings, the second direction corresponds to the Z1-Z2 direction.

The first wiring lines 21 and 22 are configured such that, when energized, a direction of current flowing in the first wiring lines 21 and a direction of current flowing in the first wiring lines 22 are opposite to each other. In FIG. 2, the direction of current flowing in the first wiring lines 21 corresponds to the Y1 direction in the Y1-Y2 direction, and the direction of current flowing in the first wiring lines 22 corresponds to the Y2 direction in the Y1-Y2 direction. Accordingly, a magnetic field generated by the first wiring lines 21 and a magnetic field generated by the first wiring lines 22 are aligned in the same direction within the first magnetic body 31. A material of the first wiring lines 21 and 22 is not particularly limited as long as the material is a conductive material, and is preferably a material based on a non-magnetic element such as copper or aluminum.

On the Z1 side in the Z1-Z2 direction (second direction) of the second magnetic body 32, the second wiring lines 23 that extend in the Y1-Y2 direction are disposed, and on the Z2 side in the Z1-Z2 direction (second direction) of the second magnetic body 32, the second wiring lines 24 that extend in the Y1-Y2 direction are disposed. The second wiring lines 23 and 24 are configured such that a direction of a magnetic field generated in the second magnetic body 32 by energization of the second wiring lines 23 and 24 is the same as a direction of a magnetic field generated in the first magnetic body 31 by energization of the first wiring lines 21 and 22. In FIG. 2, a direction of current flowing in the second wiring lines 23 is the same as the direction of current flowing in the first wiring lines 21, and a direction of current flowing in the second wiring lines 24 is the same as the direction of current flowing in the first wiring lines 22. A material of the second wiring lines 23 and 24 is not particularly limited as long as the material is a conductive material. It is preferable that the material be identical to that of the first wiring lines 21 and 22 from the viewpoints of increasing controllability of a magnetic field applied to the magnetoresistance effect element 10a and increasing ease of manufacture.

A first magnetic flux concentration section 41 that extends in the Y1-Y2 direction is disposed on the Z1 side in the Z1-Z2 direction (second direction) with respect to the first wiring lines 21. That is, the first magnetic flux concentration section 41 is provided on a side of the first wiring lines 21 opposite to a side that faces the first magnetic body 31. A first magnetic flux concentration section 42 that extends in the Y1-Y2 direction is disposed on the Z2 side in the Z1-Z2 direction (second direction) with respect to the first wiring lines 22. That is, the first magnetic flux concentration section 42 is provided on a side of the first wiring lines 22 opposite to a side that faces the first magnetic body 31. The first magnetic flux concentration sections 41 and 42 suppress divergence of a magnetic field generated by energization of the first wiring lines 21 and 22 on the side opposite to the side facing the first magnetic body 31 in the Z1-Z2 direction (second direction), and increase a magnetic flux density in the first magnetic body 31.

A second magnetic flux concentration section 43 that extends in the Y1-Y2 direction is disposed on the Z1 side in the Z1-Z2 direction (second direction) with respect to the second wiring lines 23. That is, the second magnetic flux concentration section 43 is provided on a side of the second wiring lines 23 opposite to a side that faces the second magnetic body 32. A second magnetic flux concentration section 44 that extends in the Y1-Y2 direction is disposed on the Z2 side in the Z1-Z2 direction (second direction) with respect to the second wiring lines 24. That is, the second magnetic flux concentration section 44 is provided on a side of the second wiring lines 24 opposite to a side that faces the second magnetic body 32. The second magnetic flux concentration sections 43 and 44 suppress divergence of a magnetic field generated by energization of the second wiring lines 23 and 24 on the side opposite to the side facing the second magnetic body 32 in the Z1-Z2 direction (second direction), and increase a magnetic flux density in the second magnetic body 32.

The material and thickness of the insulating section 50 may be any material and thickness as long as current flowing through the wiring lines (the first wiring lines 21 and 22 and the second wiring lines 23 and 24) can be prevented from flowing into the first magnetic body 31 and the second magnetic body 32. The insulating section 50 is preferably a diffusion suppression section that suppresses interdiffusion between the element in the wiring lines (the first wiring lines 21 and 22 and the second wiring lines 23 and 24) and the element in the first magnetic body 31 and the second magnetic body 32. When the insulating section 50 suppresses interdiffusion between the wiring lines (the first wiring lines 21 and 22 and the second wiring lines 23 and 24) and the first magnetic body 31 and the second magnetic body 32, the compositions of both are less likely to change over time, enabling higher quality stability (functional stability) of the magnetic sensor 100. From the viewpoint of enabling the insulating section 50 to function appropriately as a diffusion suppression layer, specific examples of materials for the insulating section 50 include oxide-based materials such as silica (SiO₂), alumina (Al₂O₃), and the like and nitride-based materials such as silicon nitride (Si₃N₄), aluminum nitride (AlN), and the like.

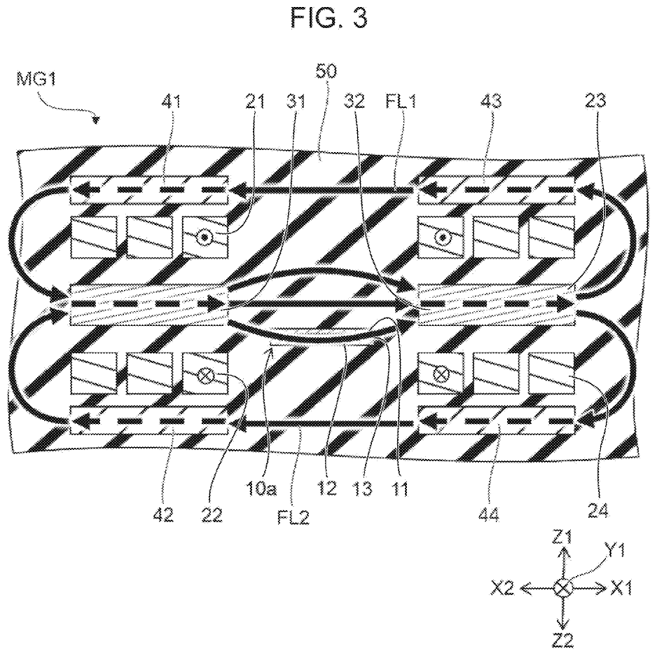

FIG. 3 is a diagram illustrating a magnetic field generated by energization of the wiring lines. Specifically, FIG. 3 corresponds to FIG. 2 with directions of magnetic flux of the magnetic field generated by energization of the first wiring lines 21 and 22 and the second wiring lines 23 and 24 additionally indicated. Magnetic flux FL1 of a magnetic field generated by energization of the first wiring lines 21 and the second wiring lines 23 toward the Y1 side in the Y1-Y2 direction travels within the first magnetic body 31 toward the X1 side in the X1-X2 direction, and radiates from an end portion on the X1 side in the X1-X2 direction of the first magnetic body 31 toward the insulating section 50. However, since the second magnetic body 32 is located on the X1 side in the X1-X2 direction of the first magnetic body 31, the magnetic flux FL1 is concentrated at an end portion on the X2 side in the X1-X2 direction of the second magnetic body 32, and travels within the second magnetic body 32 toward the X1 side in the X1-X2 direction.

The magnetic flux radiated from an end portion on the X1 side in the X1-X2 direction of the second magnetic body 32 toward the insulating section 50 travels to circulate around the second wiring lines 23 within an XZ plane, reaches the second magnetic flux concentration section 43 located on the Z1 side in the Z1-Z2 direction of the second wiring lines 23, passes through the inside of the second magnetic flux concentration section 43, and reaches an end portion on the X2 side in the X1-X2 direction of the second magnetic flux concentration section 43. The magnetic flux FL1 radiated from the end portion on the X2 side in the X1-X2 direction of the second magnetic flux concentration section 43 toward the X2 side in the X1-X2 direction is concentrated toward the first magnetic flux concentration section 41 located on the X2 side in the X1-X2 direction of the second magnetic flux concentration section 43. Accordingly, divergence of the magnetic flux FL1 toward the Z2 side in the Z1-Z2 direction of the first magnetic flux concentration section 41 and the second magnetic flux concentration section 43 is appropriately suppressed. The magnetic flux FL1 traveling in the first magnetic flux concentration section 41 toward the X2 side in the X1-X2 direction radiates from an end portion on the X2 side in the X1-X2 direction of the first magnetic flux concentration section 41, then travels to circulate around the first wiring lines 21 within the XZ plane, and reaches an end portion on the X2 side in the X1-X2 direction of the first magnetic body 31.

In this manner, the magnetic flux FL1 forms a magnetic circuit that returns to the first magnetic body 31 from the first magnetic body 31 through the insulating section 50, the second magnetic body 32, the insulating section 50, the second magnetic flux concentration section 43, the insulating section 50, and the first magnetic flux concentration section 41. Since the magnetoresistance effect element 10a is disposed in the insulating section 50 between the second magnetic flux concentration section 43 and the first magnetic flux concentration section 41, a magnetic field parallel to the sensitivity axis direction in the first direction (X1-X2 direction) is applied to the magnetoresistance effect element 10a.

Similarly, magnetic flux FL2 of a magnetic field generated by energization of the first wiring lines 22 and the second wiring lines 24 toward the Y2 side in the Y1-Y2 direction forms a magnetic circuit that returns to the first magnetic body 31 from the first magnetic body 31 through the insulating section 50, the second magnetic body 32, the insulating section 50, the second magnetic flux concentration section 44, the insulating section 50, and the first magnetic flux concentration section 42. Since the magnetoresistance effect element 10a is disposed in the insulating section 50 between the second magnetic flux concentration section 44 and the first magnetic flux concentration section 42, a magnetic field parallel to the sensitivity axis direction in the first direction (X1-X2 direction) is applied to the magnetoresistance effect element 10a.

The positional relationship between the first wiring lines 21 and 22 and the first magnetic body 31, specifically a separation distance in the second direction (Z1-Z2 direction), is defined such that a magnetic field generated by energization of the first wiring lines 21 and 22 appropriately acts on the first magnetic body 31 to form magnetic fluxes FL1 and FL2 within the first magnetic body 31. The positional relationship between the second wiring lines 23 and 24 and the second magnetic body 32, specifically a separation distance in the second direction (Z1-Z2 direction), is also defined such that a magnetic field generated by energization of the second wiring lines 23 and 24 appropriately acts on the second magnetic body 32 to form magnetic fluxes FL1 and FL2 within the second magnetic body 32.

The separation distance in the first direction (X1-X2 direction) between the first magnetic body 31 and the second magnetic body 32 is defined such that magnetic fluxes FL1 and FL2, which pass through the insulating section 50 located between the first magnetic body 31 and the second magnetic body 32 in the first direction (X1-X2 direction), are formed by a magnetic field generated during energization of the first wiring lines 21 and 22 and the second wiring lines 23 and 24. In one example, the separation distance in the first direction between the first magnetic body 31 and the second magnetic body 32 may be set such that a magnetic field generated during energization of the first wiring lines 21 and 22 is applied to the second magnetic body 32. As a specific example of a numerical range, since a magnetic flux density (unit: T) of a bias magnetic field applied to the magnetoresistance effect element 10a based on energization of the first wiring lines 21 and 22 and the second wiring lines 23 and 24 is on the order of 0.1 mT to 10 mT, the separation distance in the first direction between the first magnetic body 31 and the second magnetic body 32 may be on the order of about 0.1 μm to 10 μm.

By configuring the first magnetic field generating section MG1 and the second magnetic field generating section MG2 as described above, a bias magnetic field generated by energization of the wiring lines (the first wiring lines 21 and 22 and the second wiring lines 23 and 24) can be efficiently applied to the magnetoresistance effect element 10a, thereby stably reducing the influence of noise.

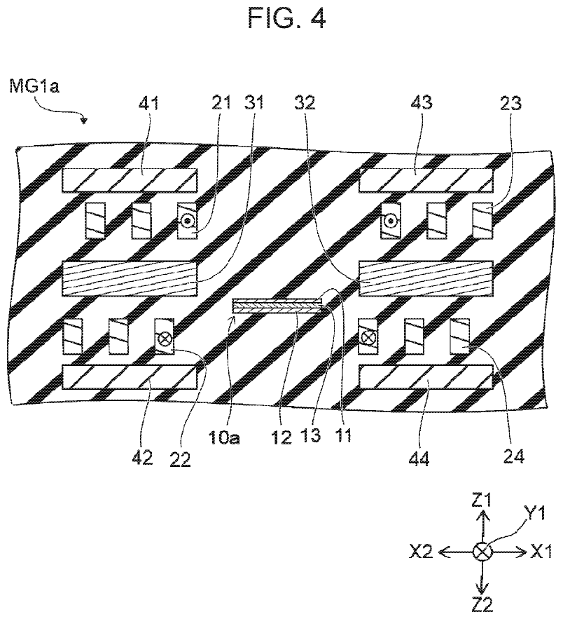

FIG. 4 is a cross-sectional view illustrating a structure of a magnetic sensor according to another embodiment of the present invention. In a first magnetic field generating section MG1a of the magnetic sensor illustrated in FIG. 4, each of the first wiring lines 21 and 22 includes a solenoid coil that is wound about a winding axis in the first direction (X1-X2 direction) to surround the first magnetic body 31, and each of the second wiring lines 23 and 24 includes a solenoid coil that is wound about a winding axis in the first direction (X1-X2 direction) to surround the second magnetic body 32. Accordingly, each of the first wiring lines 21 and 22 and the second wiring lines 23 and 24 has a portion extending in the Z1-Z2 direction. The solenoid coils of the first wiring lines 21 and 22 and the second wiring lines 23 and 24 are wound to generate magnetic flux in the same direction in the first direction (specifically, the X1 side in the X1-X2 direction).

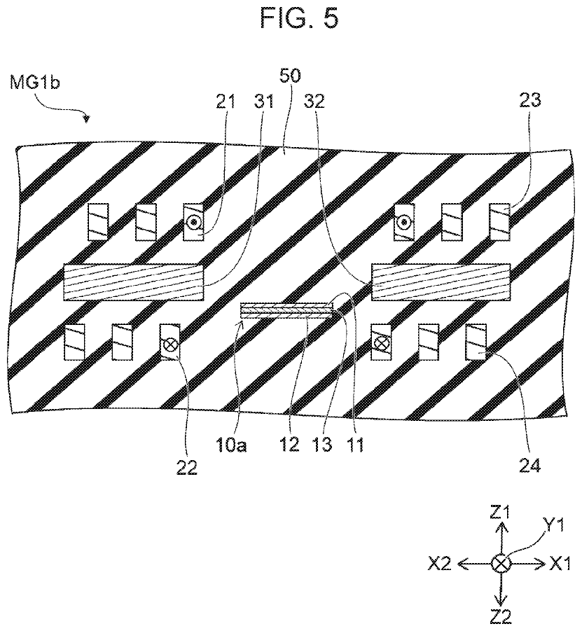

FIG. 5 is a cross-sectional view illustrating a structure of the magnetic sensor according to a first modification of another embodiment of the present invention. In a first magnetic field generating section MG1b of the magnetic sensor illustrated in FIG. 5, the first magnetic flux concentration sections 41 and 42 and the second magnetic flux concentration sections 43 and 44 are omitted, as compared with the first magnetic field generating section MG1a illustrated in FIG. 4. Accordingly, the magnetic sensor 100 that includes the first magnetic field generating section MG1b achieves higher productivity due to the absence of the magnetic flux concentration sections. In the first magnetic field generating section MG1b having such a structure, a magnetic field generated during energization of the first wiring lines 21 and 22 and the second wiring lines 23 and 24 is relatively likely to diverge on the Z1 side in the Z1-Z2 direction of the first wiring lines 21 and the second wiring lines 23, and is relatively likely to diverge on the Z2 side in the Z1-Z2 direction of the first wiring lines 22 and the second wiring lines 24. Accordingly, in the first magnetic field generating section MG1b, as compared with the first magnetic field generating section MG1a, when the amounts of current supplied to the first wiring lines 21 and 22 and the second wiring lines 23 and 24 are equal, a bias magnetic field applied to the magnetoresistance effect element 10a tends to be relatively low.

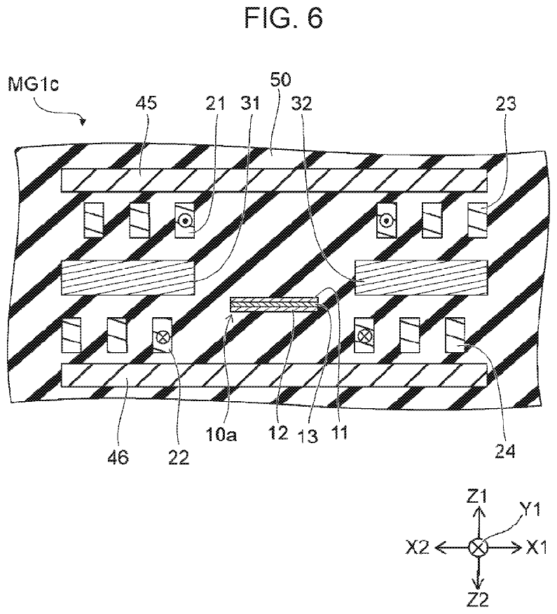

FIG. 6 is a cross-sectional view illustrating a structure of the magnetic sensor according to a second modification of another embodiment of the present invention. In a first magnetic field generating section MG1c of the magnetic sensor illustrated in FIG. 6, the first magnetic flux concentration section 41 and the second magnetic flux concentration section 43 are continuous in the first direction to form a first continuous magnetic flux concentration section 45, and the first magnetic flux concentration section 42 and the second magnetic flux concentration section 44 are continuous in the first direction to form a second continuous magnetic flux concentration section 46, as compared with the first magnetic field generating section MG1a illustrated in FIG. 4.

In the first magnetic field generating section MG1c having such a structure, a magnetic field generated during energization of the first wiring lines 21 and 22 and the second wiring lines 23 and 24 is less likely to diverge on the Z1 side in the Z1-Z2 direction (second direction) of the first wiring lines 21 and 22 and the second wiring lines 23 and 24, and is also less likely to diverge on the Z2 side in the Z1-Z2 direction (second direction) of the first wiring lines 21 and 22 and the second wiring lines 23 and 24. Accordingly, in the first magnetic field generating section MG1c, as compared with the first magnetic field generating section MG1a, when the amounts of current supplied to the first wiring lines 21 and 22 and the second wiring lines 23 and 24 are equal, a bias magnetic field applied to the magnetoresistance effect element 10a tends to be relatively high.

On the other hand, since a ferromagnetic material is located on both sides of the magnetoresistance effect element 10a in the Z1-Z2 direction (second direction), the first continuous magnetic flux concentration section 45 and the second continuous magnetic flux concentration section 46 provide a stronger shielding function against an external magnetic field than the first magnetic flux concentration sections 41 and 42 and the second magnetic flux concentration sections 43 and 44. Accordingly, the magnetic sensor 100 that includes the first magnetic field generating section MG1c tends to have lower sensitivity to an external magnetic field than the magnetic sensor 100 that includes the first magnetic field generating section MG1a. With such a structure, the magnetic sensor 100 that includes the first magnetic field generating section MG1c can provide a wider measurement range for an external magnetic field than the magnetic sensor 100 that includes the first magnetic field generating section MG1a, even when the sensitivities of the magnetoresistance effect elements 10a are the same, and is advantageous, for example, when the intensity of the external magnetic field to be measured is high.

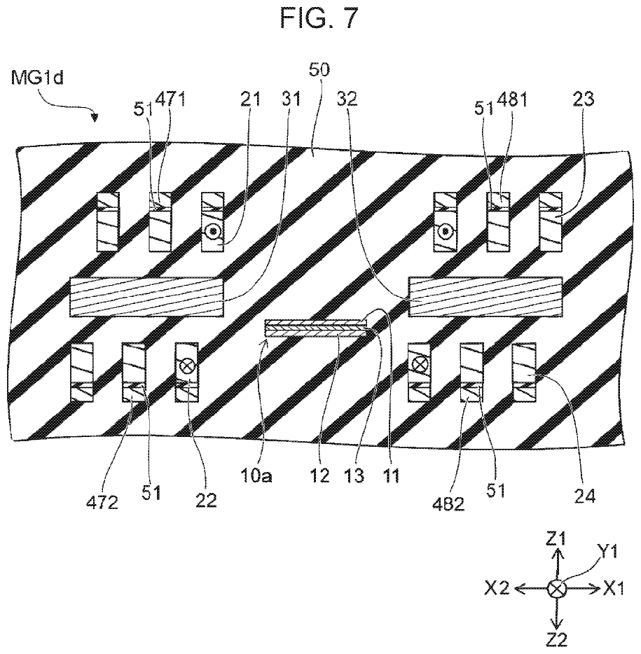

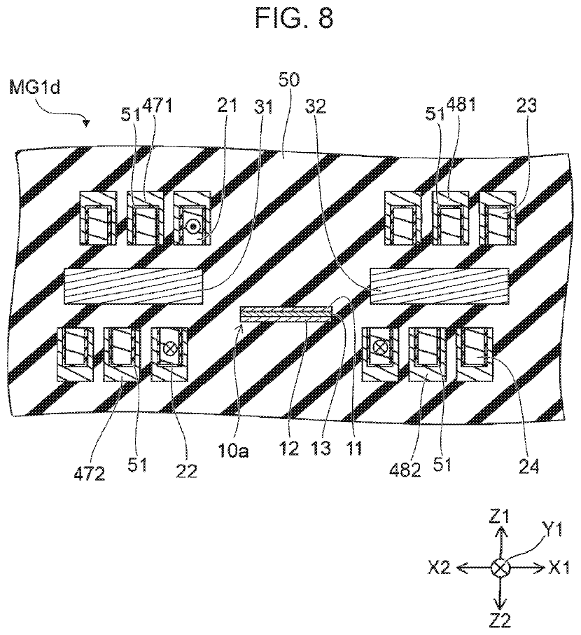

FIG. 7 is a cross-sectional view illustrating a structure of the magnetic sensor according to a third modification of another embodiment of the present invention. FIG. 8 is a cross-sectional view illustrating a structure of the magnetic sensor according to a fourth modification of another embodiment of the present invention. As illustrated in FIGS. 7 and 8, the magnetic flux concentration sections may be provided for respective wiring lines. In FIG. 7, a first magnetic flux concentration section 471 is disposed on the Z1 side in the Z1-Z2 direction (second direction) of the first wiring line 21 with an individual insulating section 51 therebetween. The individual insulating section 51 may include a material similar to that of the insulating section 50, or may include the same material as the insulating section 50. A first magnetic flux concentration section 472 is disposed on the Z2 side in the Z1-Z2 direction (second direction) of the first wiring line 22 with the individual insulating section 51 therebetween. Similarly, a second magnetic flux concentration section 481 is disposed on the Z1 side in the Z1-Z2 direction (second direction) of the second wiring line 23 with the individual insulating section 51 therebetween, and a second magnetic flux concentration section 482 is disposed on the Z2 side in the Z1-Z2 direction (second direction) of the second wiring line 24 with the individual insulating section 51 therebetween.

As illustrated in FIG. 8, the first magnetic flux concentration sections 471 and 472 and the second magnetic flux concentration sections 481 and 482 may extend to cover surfaces of the first wiring lines 21 and 22 and the second wiring lines 23 and 24 that face the first direction (X1-X2 direction), respectively. Even in this case, it is preferable that the individual insulating sections 51 be provided between the first magnetic flux concentration sections 471 and 472 and the first wiring lines 21 and 22, and between the second magnetic flux concentration sections 481 and 482 and the second wiring lines 23 and 24, respectively.

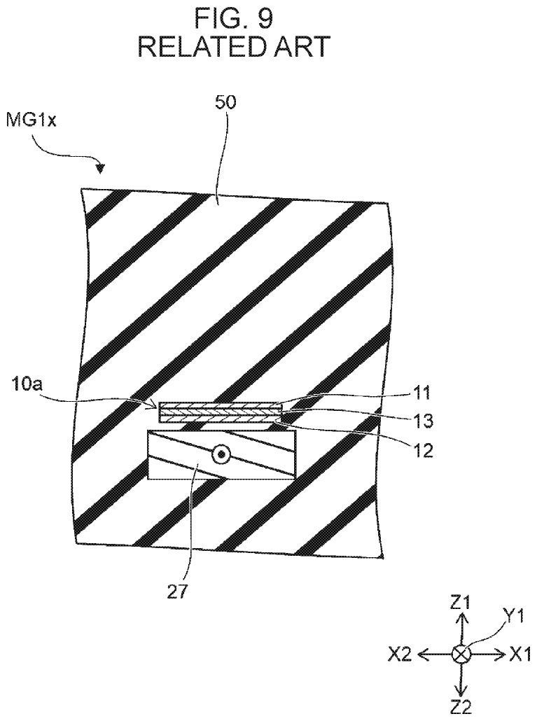

FIG. 9 is a cross-sectional view illustrating a structure of a magnetic sensor according to a related art. A first magnetic field generating section MG1x includes a single wiring line 27 that is provided on the Z2 side in the Z1-Z2 direction of the magnetoresistance effect element 10a, and the insulating section 50 disposed between the magnetoresistance effect element 10a and the single wiring line 27.

Simulations were performed for magnetic sensors 100 that include magnetic field generating sections that have shapes based on the first magnetic field generating sections MG1a, MG1b, MG1c, and MG1x, respectively. The first wiring lines 21 and 22, the second wiring lines 23 and 24, and the single wiring line 27 were all made of copper, and the first magnetic body 31, the second magnetic body 32, and the magnetic flux concentration sections (the first magnetic flux concentration sections 41 and 42, the second magnetic flux concentration sections 43 and 44, the first continuous magnetic flux concentration section 45, and the second continuous magnetic flux concentration section 46) were all made of permalloy.

The magnetoresistance effect element 10a was disposed such that it was separated from the first magnetic body 31 and the second magnetic body 32 by equal distances in the first direction, and such that the surface of the magnetoresistance effect element 10a on the Z1 side in the Z1-Z2 direction (second direction) was flush with the surfaces of the first magnetic body 31 and the second magnetic body 32 on the Z2 side in the Z1-Z2 direction (second direction).

Other dimensions were set as follows. In the following description, the Y1-Y2 direction is referred to as a third direction.
Shape of the magnetoresistance effect elements 10: a cube of 1 μm in the first direction×80 μm in the third direction.
Shape of each of the first magnetic body 31 and the second magnetic body 32: a cube of 16 μm in the first direction×80 μm in the third direction×2 μm in the second direction
First wiring lines 21 and 22: three copper wires each having 2 μm in the first direction×80 μm in the third direction×1.5 μm in the second direction (pitch in the first direction: 3 μm), arranged on the X2 side from a position shifted by 4 μm toward the X2 side from the end portion on the X1 side in the X1-X2 direction (first direction) of the first magnetic body 31
Second wiring lines 23 and 24: three copper wires each having 2 μm in the first direction×80 μm in the third direction×1.5 μm in the second direction (pitch in the first direction: 3 μm), arranged on the X1 side from a position shifted by 4 μm toward the X1 side from the end portion on the X2 side in the X1-X2 direction (first direction) of the second magnetic body 32
Shape of each of the first magnetic flux concentration sections 41 and 42 and the second magnetic flux concentration sections 43 and 44 in the first magnetic field generating section MG1a: a cube of 16 μm in the first direction×80 μm in the third direction×0.5 μm in the second direction
Shape of each of the first continuous magnetic flux concentration section 45 and the second continuous magnetic flux concentration section 46 in the first magnetic field generating section MG1c: a cube of 34 μm in the first direction×80 μm in the third direction×0.5 μm in the second direction
Separation distance in the first direction between the first magnetic body 31 and the second magnetic body 32: 2 μm
Separation distance in the second direction between the magnetic bodies (the first magnetic body 31 and the second magnetic body 32) and the wiring lines (the first wiring lines 21 and 22 and the second wiring lines 23 and 24): 0.25 μm
Separation distance in the second direction between the magnetic flux concentration sections (the first magnetic flux concentration sections 41 and 42, the second magnetic flux concentration sections 43 and 44, the first continuous magnetic flux concentration section 45, and the second continuous magnetic flux concentration section 46) and the wiring lines (the first wiring lines 21 and 22 and the second wiring lines 23 and 24): 0.25 μm
Single wiring line 27 in the first magnetic field generating section MG1x: a copper wire having 2 μm in the first direction×80 μm in the third direction×1.5 μm in the second direction
Separation distance in the second direction between the single wiring line 27 and the magnetoresistance effect element 10a in the first magnetic field generating section MG1x: 0.25 μm

Bias magnetic fields Bb were obtained by applying, to the first wiring lines 21 and 22 and the second wiring lines 23 and 24 of the first magnetic field generating sections MG1a to MG1c, a current corresponding to a current amount at which a magnetic field (bias magnetic field Bb) generated by energization of the single wiring line 27 of the first magnetic field generating section MG1x is 0.16 mT at the magnetoresistance effect element 10a. Further, an external magnetic field Bo corresponding to an external magnetic field of 1.00 mT measured at the magnetoresistance effect element 10a of the first magnetic field generating section MG1x was applied to the first magnetic field generating sections MG1a to MG1c, and external magnetic fields Bo at the respective magnetoresistance effect elements 10a of the first magnetic field generating sections MG1a to MG1c were obtained. The simulation results are shown in Table 1.

TABLE 1

| | Bb/mT | Bo/mT | Remarks |
|---|---|---|---|
| MG1x | 0.16 | 1.00 | Comparative Example |
| MG1b | 0.63 | 3.39 | Example |
| MG1a | 0.87 | 2.85 | Example |
| MG1c | 1.19 | 0.37 | Example |

Although the first magnetic field generating section MG1b, which is included in the magnetic sensor 100 according to the embodiment, does not include the magnetic flux concentration sections, it was confirmed that a bias magnetic field Bb approximately four times greater than that of the first magnetic field generating section MG1x of the known magnetic sensor was applied, and that the first magnetic field generating section MG1b including the magnetic bodies (the first magnetic body 31 and the second magnetic body 32) had a favorable function of amplifying the bias magnetic field Bb. Further, with respect to the external magnetic field Bo, it was confirmed that, in the first magnetic field generating section MG1b, a value approximately three times higher than that of the first magnetic field generating section MG1x was detected at the magnetoresistance effect element 10a, and that the magnetic bodies (the first magnetic body 31 and the second magnetic body 32) functioned as a yoke for the external magnetic field Bo.

In the first magnetic field generating section MG1a, which includes the first magnetic flux concentration sections 41 and 42 and the second magnetic flux concentration sections 43 and 44 as compared with the first magnetic field generating section MG1b, a bias magnetic field Bb approximately 40% higher than that of the first magnetic field generating section MG1b was detected, and it was confirmed that the amplification function of the bias magnetic field Bb in the first magnetic field generating section MG1a was higher than that in the first magnetic field generating section MG1b. The external magnetic field Bo detected in the first magnetic field generating section MG1a was approximately 15% lower than that in the first magnetic field generating section MG1b. It is considered that the first magnetic flux concentration sections 41 and 42 and the second magnetic flux concentration sections 43 and 44 functioned as a shield against the external magnetic field Bo, as compared with the first magnetic field generating section MG1b.

In the first magnetic field generating section MG1c, which has a structure in which the magnetic flux concentration sections are continuous in the first direction as compared with the first magnetic field generating section MG1a, a bias magnetic field Bb approximately 40% higher than that of the first magnetic field generating section MG1a was detected, and it was confirmed that the first magnetic field generating section MG1c had a further enhanced amplification function for the bias magnetic field Bb as compared with the first magnetic field generating section MG1a. The external magnetic field Bo detected in the first magnetic field generating section MG1c was as low as approximately 15% of that detected in the first magnetic field generating section MG1a. It is considered that the first continuous magnetic flux concentration section 45 and the second continuous magnetic flux concentration section 46, which are continuous in the first direction, functioned as a strong shield against the external magnetic field Bo because a ferromagnetic material is disposed on both sides of the magnetoresistance effect element 10a in the Z1-Z2 direction (second direction).

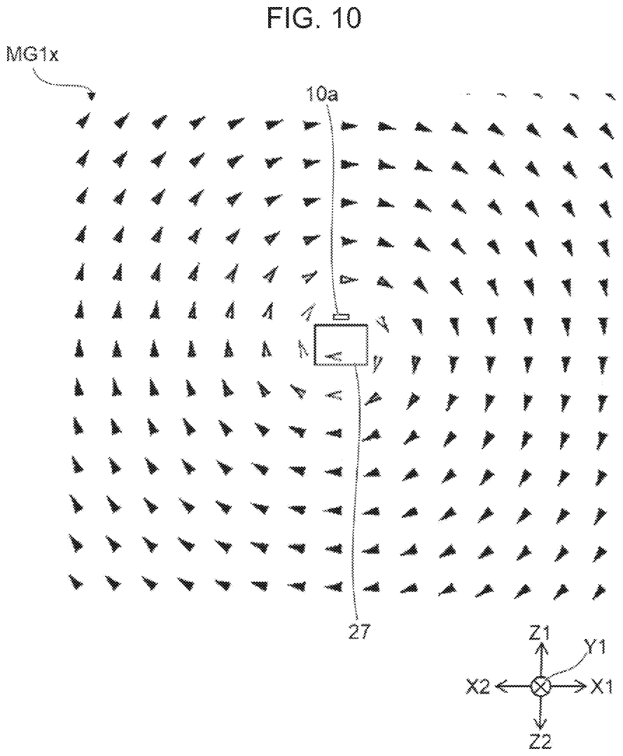

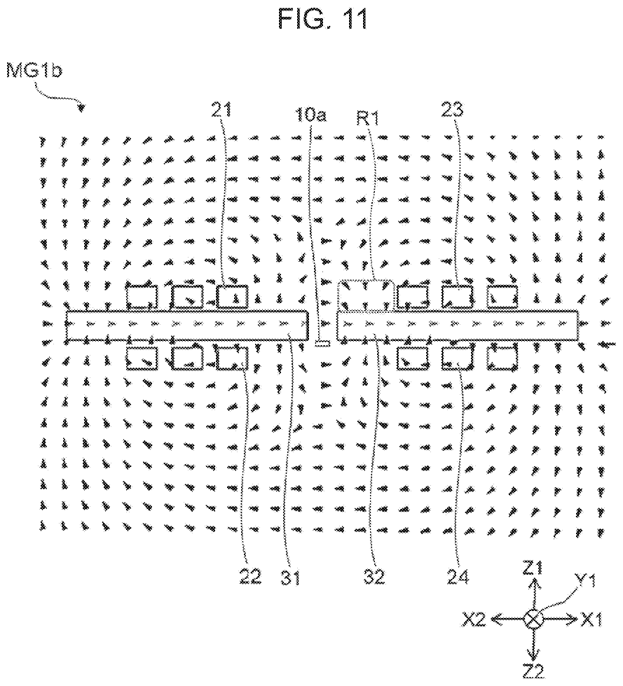

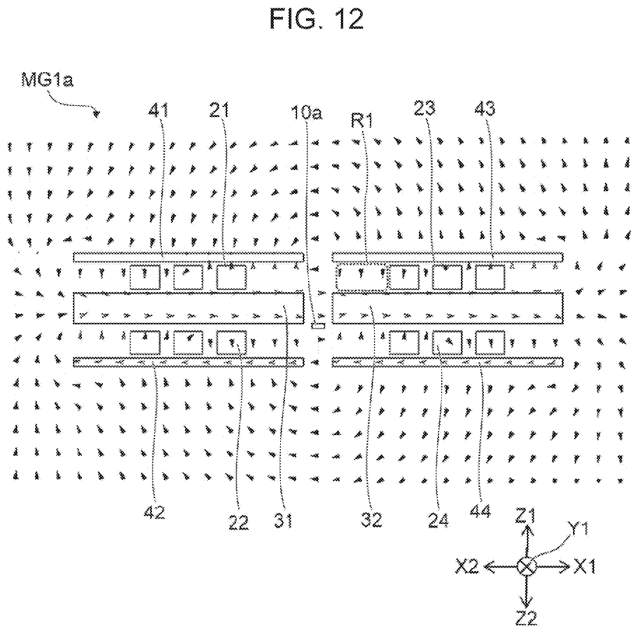

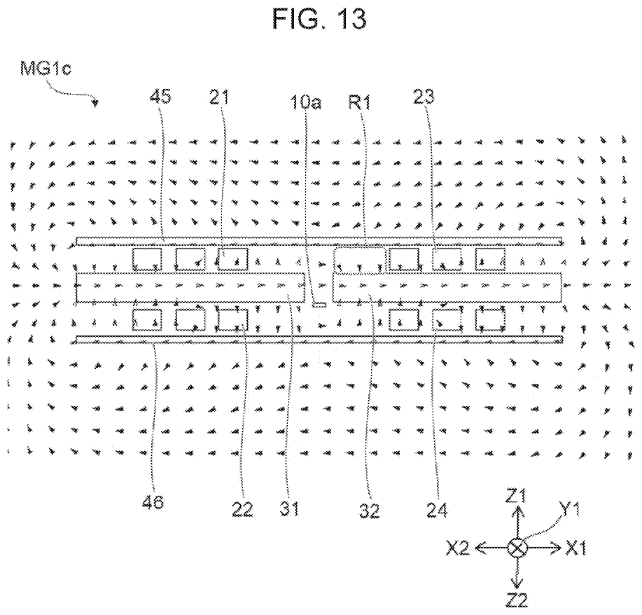

The simulation results are shown in FIGS. 10 to 13. FIG. 10 shows a simulation result of a magnetic field generated by the first magnetic field generating section MG1x, FIG. 11 shows a simulation result of a magnetic field generated by the first magnetic field generating section MG1b, FIG. 12 shows a simulation result of a magnetic field generated by the first magnetic field generating section MG1a, and FIG. 13 shows a simulation result of a magnetic field generated by the first magnetic field generating section MG1c.

As shown in FIG. 10, in the first magnetic field generating section MG1x of the known magnetic sensor, a magnetic field circulating concentrically around the single wiring line 27 was formed. Accordingly, a magnetic field generated by energization of the single wiring line 27 passed through the insulating section 50 and was directly applied to the magnetoresistance effect element 10a.

On the other hand, as shown in FIG. 11, in the first magnetic field generating section MG1b of the magnetic sensor 100 according to an example of the embodiment, a magnetic field generated by energization of the first wiring lines 21 and 22 and a magnetic field generated by energization of the second wiring lines 23 and 24 were amplified by passing through the first magnetic body 31 and the second magnetic body 32, which have higher relative permeability than the insulating section 50, and were applied to the magnetoresistance effect element 10a located between the first magnetic body 31 and the second magnetic body 32. On the Z1 side in the Z1-Z2 direction (second direction) of the first wiring lines 21 and 22 and the second wiring lines 23 and 24, and on the Z2 side in the Z1-Z2 direction (second direction) of the first wiring lines 21 and 22 and the second wiring lines 23 and 24, the generated magnetic field passed through the insulating section 50, as in the case of the first magnetic field generating section MG1x.

As shown in FIG. 12, in the first magnetic field generating section MG1a of the magnetic sensor 100 according to an example of the embodiment, a magnetic field generated by energization of the first wiring lines 21 and 22 and a magnetic field generated by energization of the second wiring lines 23 and 24 were amplified by passing through the first magnetic body 31 and the second magnetic body 32, which have higher relative permeability than the insulating section 50, and were applied to the magnetoresistance effect element 10a located between the first magnetic body 31 and the second magnetic body 32. The generated magnetic field passed through the first magnetic flux concentration section 41 and the second magnetic flux concentration section 43 on the Z1 side in the Z1-Z2 direction (second direction) of the first wiring lines 21 and the second wiring lines 23. The direction of magnetic flux of the generated magnetic field was distributed to connect the first magnetic flux concentration section 41 and the second magnetic flux concentration section 43 between the first magnetic flux concentration section 41 and the second magnetic flux concentration section 43. On the Z1 side in the Z1-Z2 direction (second direction) of the first magnetic flux concentration section 41 and the second magnetic flux concentration section 43, the direction of the magnetic flux of the generated magnetic field was distributed to circulate around a region between the first magnetic flux concentration section 41 and the second magnetic flux concentration section 43. From this distribution, it was understood that the region between the first magnetic flux concentration section 41 and the second magnetic flux concentration section 43 functioned like a magnetic gap in the magnetic circuit of the generated magnetic field.

The generated magnetic field passed through the first magnetic flux concentration section 42 and the second magnetic flux concentration section 44 on the Z2 side in the Z1-Z2 direction (second direction) of the first wiring lines 22 and the second wiring lines 24. The direction of magnetic flux of the generated magnetic field was distributed to connect the first magnetic flux concentration section 42 and the second magnetic flux concentration section 44 between the first magnetic flux concentration section 42 and the second magnetic flux concentration section 44. On the Z2 side in the Z1-Z2 direction (second direction) of the first magnetic flux concentration section 42 and the second magnetic flux concentration section 44, the direction of the magnetic flux of the generated magnetic field was distributed to circulate around a region between the first magnetic flux concentration section 42 and the second magnetic flux concentration section 44. From this distribution, it was understood that the region between the first magnetic flux concentration section 42 and the second magnetic flux concentration section 44 functioned like a magnetic gap in a magnetic circuit of the generated magnetic field.

As shown in FIG. 13, in the first magnetic field generating section MG1c of the magnetic sensor 100 according to an example of the embodiment, as compared with the first magnetic field generating section MG1a shown in FIG. 12, the distribution of magnetic flux differed in the outermost region in the Z1-Z2 direction (second direction), specifically on the Z1 side in the Z1-Z2 direction (second direction) of the first continuous magnetic flux concentration section 45 and on the Z2 side in the Z1-Z2 direction (second direction) of the second continuous magnetic flux concentration section 46. In particular, in the first magnetic field generating section MG1c, since there was no portion functioning like a magnetic gap as in the first magnetic field generating section MG1a, the magnetic flux was distributed in a direction of the X1-X2 direction (first direction) to connect both sides of the first continuous magnetic flux concentration section 45 in the X1-X2 direction, and was also distributed in a direction of the X1-X2 direction (first direction) to connect both sides of the second continuous magnetic flux concentration section 46 in the X1-X2 direction (first direction).

With respect to the results shown in FIGS. 11 to 13, a further comparison was made focusing on magnetic flux in a region (first region R1, indicated by dashed lines in FIGS. 11 to 13) on the X2 side in the X1-X2 direction (first direction) of the second wiring line 23 and on the Z1 side in the Z1-Z2 direction (second direction) of the second magnetic body 32. In the first magnetic field generating section MG1b shown in FIG. 11, a magnetic field generated by the second wiring lines 23 circulated around the second wiring lines 23 on the Z1 side in the Z1-Z2 direction (second direction), and therefore, in the first region R1, the magnetic flux was directed toward the Z2 side in the Z1-Z2 direction (second direction) and toward the second magnetic body 32. Accordingly, magnetic flux that entered the second magnetic body 32 through the first region R1 flowed inside the second magnetic body 32 in the X1 direction of the X1-X2 direction (first direction), and was not applied to the magnetoresistance effect element 10a.

In the first magnetic field generating section MG1a shown in FIG. 12, since a magnetic field generated by the second wiring lines 23 passed through the second magnetic flux concentration section 43 on the Z1 side in the Z1-Z2 direction (second direction), most of the magnetic flux emitted from the second magnetic flux concentration section 43 was directed toward the first magnetic flux concentration section 41, and magnetic flux directed toward the Z2 side in the Z1-Z2 direction (second direction) in the first region R1 was smaller than that in the case of the first magnetic field generating section MG1b. Accordingly, in the first magnetic field generating section MG1a, the component of the magnetic field generated by the second wiring lines 23 and applied to the magnetoresistance effect element 10a was greater than that in the first magnetic field generating section MG1b.

In the first magnetic field generating section MG1c shown in FIG. 13, in contrast to the first magnetic field generating section MG1a, in which the second magnetic flux concentration section 43 and the first magnetic flux concentration section 41 were magnetically coupled with magnetic gaps therebetween, a configuration was employed in which the first continuous magnetic flux concentration section 45 having no magnetic gap was provided. Therefore, the amount of magnetic flux directed toward the Z2 side in the Z1-Z2 direction (second direction) in the first region R1 is smaller than that in the case of the first magnetic field generating section MG1a. Accordingly, in the first magnetic field generating section MG1c, most of the magnetic field generated by the second wiring lines 23 passed through the first continuous magnetic flux concentration section 45 and reached the first magnetic body 31, and the component applied to the magnetoresistance effect element 10a was greater than that in the first magnetic field generating section MG1a.

It should be noted that the above-described embodiments are provided to facilitate understanding of the present invention and do not limit the present invention. Accordingly, the components disclosed in the embodiments are intended to include all design changes and equivalents that fall within the technical scope of the present invention. In the first magnetic field generating section MG1a and other configurations according to the above embodiments, the first wiring lines 21 and 22 are provided corresponding to the first magnetic body 31, and the second wiring lines 23 and 24 are provided corresponding to the second magnetic body 32; however, the present invention is not limited thereto, and wiring lines may be provided corresponding to only one of the first magnetic body 31 and the second magnetic body 32. For example, the first wiring lines 21 and 22 may be provided corresponding to the first magnetic body 31, and the second wiring lines 23 and 24 may be omitted. Furthermore, only one of the first wiring lines 21 and 22 may be provided. In such cases, when a magnetic field generated by energization of both or one of the first wiring lines 21 and 22 passes through the first magnetic body 31 and is emitted from an end portion on the X1 side in the X1-X2 direction of the first magnetic body 31, the second magnetic body 32 performs a magnetic attraction function that directs the emitted magnetic flux preferentially in the first direction (X1-X2 direction). As a result, the generated magnetic field has a larger component directed in the sensitivity axis direction (the first direction) of the magnetoresistance effect element 10a, thereby increasing detection sensitivity of the magnetoresistance effect element 10a. Alternatively, in the first magnetic field generating section MG1a and other configurations according to the above embodiments, the stacking direction of the magnetoresistance effect element 10a is parallel to the second direction; however, the present invention is not limited thereto, and the stacking direction may be parallel to a direction other than the second direction, for example, the third direction (Y1-Y2 direction).

What is claimed is:

1. A magnetic sensor comprising:
a first magnetic body and a second magnetic body spaced apart from each other in a first direction;
a magnetoresistance effect element having a sensitivity axis parallel to the first direction and located between the first magnetic body and the second magnetic body in the first direction;
first wiring lines located on a second direction side, the second direction being orthogonal to the first direction, of the first magnetic body, the first wiring lines being configured, when energized, to generate a magnetic field such that magnetic flux passing through the first magnetic body has a component in the first direction; and
an insulating section located between the first wiring lines and the first magnetic body.

2. The magnetic sensor according to claim 1, further comprising:
second wiring lines disposed on the second-direction side of the second magnetic body with the insulating section therebetween, the second wiring lines being configured, when energized, to generate a magnetic field such that magnetic flux passing through the second magnetic body has a component in the first direction, wherein
a direction of the component in the first direction of the magnetic flux passing through the first magnetic body in accordance with the magnetic field generated by energization of the first wiring lines is the same as a direction of the component in the first direction of the magnetic flux passing through the second magnetic body in accordance with the magnetic field generated in the second magnetic body by energization of the second wiring lines.

3. The magnetic sensor according to claim 1, wherein the insulating section includes a diffusion suppression section.

4. The magnetic sensor according to claim 1, wherein the first wiring lines are provided on both sides of the first magnetic body in the second direction.

5. The magnetic sensor according to claim 2, wherein the second wiring lines are provided on both sides of the second magnetic body in the second direction.

6. The magnetic sensor according to claim 1, further comprising a first magnetic flux concentration section provided on a side of the first wiring lines opposite to a side facing the first magnetic body, the first magnetic flux concentration section including a ferromagnetic material.

7. The magnetic sensor according to claim 2, further comprising a second magnetic flux concentration section provided on a side of the second wiring lines opposite to a side facing the second magnetic body, the second magnetic flux concentration section including a ferromagnetic material.

8. The magnetic sensor according to claim 7, further comprising a first magnetic flux concentration section provided on a side of the first wiring lines opposite to a side facing the first magnetic body, the first magnetic flux concentration section including a ferromagnetic material.

9. The magnetic sensor according to claim 8, wherein, as viewed in the second direction, the magnetoresistance effect element does not overlap either the first magnetic flux concentration section or the second magnetic flux concentration section.

10. The magnetic sensor according to claim 8, wherein the first magnetic flux concentration section and the second magnetic flux concentration section are continuously connected in the first direction.
